(19) United States
(12) Patent Application Publication
(10) Pub. No.: US 2003/0221618 A1
(43) Pub. Date: Dec. 4, 2003

(54) Apparatus for producing sheeting

(75) Inventors: Makoto Kashiwaya, Kanagawa (JP); Junji Nakada, Kanagawa (JP); Norio Shibata, Kanagawa (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/449,007

(22) Filed: Jun. 2, 2003

(30) Foreign Application Priority Data
May 31, 2002 (JP) 2002-158649

(51) Int. Cl. C23C 16/00

(52) U.S. Cl. 118/718

(57) ABSTRACT

The apparatus for producing sheeting includes a transport unit which transports a web of sheeting along its length direction, a pattern transfer unit which forms a pattern on a surface of the sheeting by transfer and that is provided in a pathway where the web of sheeting is transported by the transport unit, a film depositing unit which performs vacuum film deposition on the patterned surface of the web of sheeting and that is provided downstream of the pattern transfer unit in the pathway, and a pressure retaining unit which retains pressure within the film depositing unit and that is provided in a region of the film depositing unit into which the web of sheeting is transported and in a region of the film depositing unit from which the web of sheeting emerges.

### BACKGROUND OF THE INVENTION

This invention relates to the thin film technology based on vacuum film deposition techniques. More particularly, the invention relates to an apparatus capable of efficient and productive manufacture of the sheeting that has a patterned functional thin film formed thereon.

The deposition of the patterned functional thin film on the sheeting has been studied in a variety of applications. For example, JP 7-27079 B discloses the use of an improved phosphor sheet (a radiation image transforming panel) in a radiation image reading apparatus in order to produce sharper radiation image. The phosphor sheet has a stimulable phosphor layer which is vacuum deposited on a substrate having an embossed pattern, whereby the stimulable phosphor layer is provided with a block structure of fine columnar crystals that reflects the embossed pattern of the substrate and which is crystallographically discontinuous.

JP 2001-283731 A discloses a phosphor layer to be used in a radiation imaging apparatus such as an X-ray diagnostic apparatus or the like. To produce the phosphor layer, base scintillator crystals are patterned onto a substrate and columns of the same scintillator crystals are grown on the base by vacuum evaporation or the like. The thus formed phosphor layer has an array of independent columnar crystals of uniform shape and size that contribute higher resolution.

In magnetic recording media such as hard disks (HDs) and flexible disks (FDs), attempts are being made to form patterns that divide the magnetic layer into regions so that individually independent, fine magnetic fields that conform to the pattern are formed to thereby produce recording media having higher recording density and larger capacity.

In order to produce such patterned functional thin films by vacuum deposition, the following procedure is commonly adopted: a photolithographic process involving etching and resist-assisted film deposition is typically employed to provide a surface of a substrate with an embossed pattern that conforms to a pattern of a thin film to be deposited and, thereafter, the substrate is set in a vacuum film depositing apparatus and subjected to a film deposition process.

However, high productivity is not obtained by this batchwise method so that a product cost is getting higher.

### SUMMARY OF THE INVENTION

An object of the present invention is to solve the aforementioned problems of the prior art and to provide an apparatus for producing a sheeting with which the sheeting having a patterned functional thin film formed by vacuum deposition techniques can be manufactured with high efficiency and productivity.

In order to attain the object described above, the present invention provides an apparatus for producing sheeting, comprising: transport means for transporting a web of sheeting along its length direction; pattern transfer means for forming a pattern on a surface of the sheeting by transfer, the pattern transfer means being provided in a pathway where the web of sheeting is transported by the transport means; film depositing means for performing vacuum film deposition on the patterned surface of the web of sheeting, the film depositing means being provided downstream of the pattern transfer means in the pathway; and pressure retaining means for retaining pressure within the film depositing means, the pressure retaining means being provided in a region of the film depositing means into which the web of sheeting is transported and in a region of the film depositing means from which the web of sheeting emerges.

It is preferable that the transport means has delivery sub-means for delivering the web of sheeting from a roll of sheeting and take-up sub-means for taking up the web of sheeting on the surface of which the vacuum film deposition is performed.

It is another preferable that the pattern transfer means comprises a transfer roller having up and down areas on its cylindrical surface that correspond to the pattern to be transferred and a nip roller that cooperates with the transfer roller to hold the web of sheeting between the transfer and the nip rollers.

### BRIEF DESCRIPTION OF THE DRAWINGS

FIG. 1 shows in concept an example in which the apparatus of the invention for producing the sheeting is employed as an apparatus for producing a stimulable phosphor sheet;

FIG. 2A shows in concept how an embossed pattern is formed on a surface of a substrate as it is set in the apparatus shown in FIG. 1; and

FIG. 2B shows in concept how stimulable phosphor crystals are deposited over the embossed pattern.

### DESCRIPTION OF THE PREFERRED EMBODIMENT

The apparatus of the invention for producing a sheeting is described below in detail with reference to the preferred embodiment illustrated in the accompanying drawings.

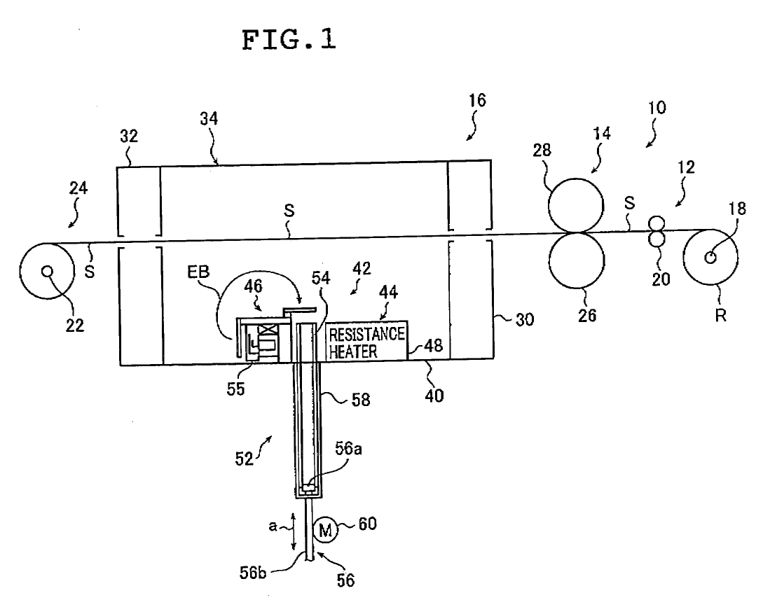

FIG. 1 shows in concept an example of the apparatus of the invention for producing the sheeting. The apparatus indicated by 10 in FIG. 1 is for producing a stimulable phosphor sheet (hereunder referred to simply as a phosphor sheet) which comprises a web of sheeting S as a substrate that has a stimulable phosphor layer (hereunder referred to simply as a phosphor layer) formed on a surface. The three basic components of the apparatus 10 are a transport unit 12 of the sheeting S, a transfer section 14 and a film depositing section 16.

In the illustrated case, the web of sheeting S is transported in a longitudinal direction by the transport unit 12, provided with a predetermined (embossed) pattern on a surface in the transfer section 14, and then forwarded into the film depositing section 16 where a phosphor layer (CsBr:Eu in the illustrated case) is deposited on the patterned surface to complete the phosphor sheet.

The illustrated case is where the apparatus of the present invention for producing the sheeting is employed as an apparatus for producing phosphor sheets. However, the present invention is by no means limited to this case and as long as the apparatus is capable of forming the patterned functional thin film on the web of substrate by vacuum film deposition techniques, it can be employed in a variety of applications including the manufacture of varieties of optical components and magnetic recording media.

In the illustrated case, the web of sheeting S being the substrate (which is hereunder referred to simply as sheet S) is first supplied as a roll of sheeting R (which is hereunder referred to simply as roll R), then unwound for the deposition of the phosphor layer in the manner just described above, and finally rewound in a roll form.

In the apparatus 10, the transport unit 12 is a known means of transporting webs of sheeting, which unwinds the sheet S from the roll R, transports it through a specified pathway where the transfer section 14 and the film depositing section 16 are provided, and again rewinds the sheet S in the roll form. The basic components of the transport unit 12 are a shaft 18 for rotatably supporting the roll R, a delivery roller pair 20 that delivers the sheet S as it is unwound from the roll R, and a take-up section 24 where a take-up roller 22 is rotated to rewind the sheet S into the roll form after the formation of the phosphor layer.

Needless to say, the transport unit 12 may optionally be equipped with a variety of members in the known sheeting transport means, as exemplified by a transport roller pair that transports the sheet S as it is held between the rollers, as well as rollers, roller pairs, guide plates, etc. that define the transport pathway of the sheet S.

In the illustrated case, the whole process starting with the supply of the sheet S from the roll R and ending with the rewinding of the sheet S involves the formation of the pattern by transfer, and the film deposition that are performed continuously at constant sheeting speed transport. Therefore, the speed at which the sheet S is transported by the transport unit 12 may be determined as appropriate based on a variety of factors such as the rate of the film deposition in the film depositing section 16 to be described later and the thickness of the film to be deposited.

In the present invention, the transport speed of the sheet S need not be uniform throughout the whole transport pathway and it may optionally be varied from place to place. In this case, the difference of the transport speed in each place may be absorbed by any known means such as forming a loop (slackening) of the sheet S or stopping the transport of the sheet S in a selected place.

In the invention, the substrate sheet S is not limited in any particular way and various materials can be used depending upon the sheeting to be finally produced. Exemplary substrate materials include resin films such as poly (ethylene terephthalate) film and polyamide film, and strips of metals such as stainless steel, aluminum and iron. If the intended product is a phosphor sheet as in the illustrated case, a poly (ethylene terephthalate) film may be employed.

The thickness and width of the sheet S are also not subject to any limitation and appropriate values may be chosen in accordance with a specific use of the sheeting.

The transfer section 14 is provided within the pathway in which the sheet S is transported by the transport unit 12 as just described above. In the illustrated case, the transfer section 14 comprises a transfer roller 26 provided in contact with the (lower) side of the sheet S where a film is to be deposited and a nip roller 28 which cooperates with the transfer roller 26 to transport the sheet S as it is held between the two rollers.

The transfer roller 26 has an embossed surface, that is to say, up and down areas on its cylindrical surface (circumference surface) that conforms to the pattern of the phosphor layer (functional thin film) which is to be later deposited. The transfer section 14 is part of the transport unit 12 and the transfer roller 26 rotates as a drive roller at a speed associated with the transport speed of the sheet S. Instead, the drive roller may be the nip roller 28. Alternatively, if the sheet S has sufficient strength to withstand pattern transfer as it is held between the transfer roller 26 and the nip roller 28, the two rollers may be designed as follower rollers that are driven by the transport of the sheet S.

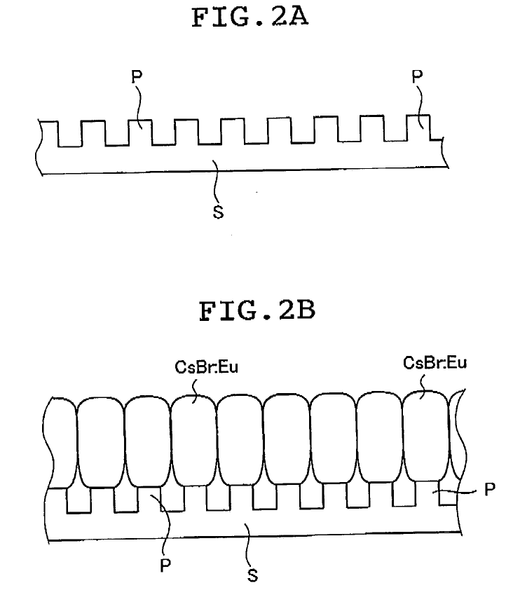

In the transfer section 14, the sheet S is transported as it is held between the transfer roller 26 and the nip roller 28; in consequence, the embossed surface of the transfer roller 26 is pressed onto the surface of the sheet S where a phosphor layer is to be deposited, whereupon the embossed pattern is transferred to the sheet S and the correspondingly embossed pattern is formed on the surface where a phosphor layer is to be deposited. In the illustrated case, a pattern is formed so that a large number of projections which are shown conceptually in FIG. 2A and indicated by P are provided in array on the surface of the sheet S where a phosphor layer is to be deposited (for details, see below).

By using this transfer roller 26, an embossed pattern can be formed continuously and efficiently on the surface of the sheet S where a phosphor layer is to be deposited.

The force of holding by the two rollers, namely, the force at which the transfer roller 26 is pressed against the sheet S in order to form an embossed pattern, may be determined as appropriate for various factors including the hardness of the sheet S, the depth of valleys to be gouged in the surface of the sheet S, etc.

In the present invention, either the transfer roller 26 or the nip roller 28 or both may be equipped with a heating means or any other suitable method may be employed in order to form an embossed pattern on the surface of the sheet S by thermal transfer.

In the present invention, the pattern to be formed on the specified surface of the sheet S, namely, the pattern of the thin film to be formed on that surface is not limited in any particular way and a variety of patterns may be chosen depending on specific uses to which the sheet S is to be put after forming the functional thin film, such as optical components, magnetic recording media, etc as described above.

In the illustrated case, an alkali metal halide based stimulable phosphor such as CsBr:Eu is deposited to form a stimulable phosphor layer and, to this end, columnar crystals are grown by vacuum film deposition. In particular, if the stimulable phosphor is deposited on a substrate having an embossed pattern as an array of projections, aligned columnar crystals grow up straight on the projections that serve as bases, thereby producing a high-performance stimulable phosphor sheet capable of satisfactory sharp image reproduction.

Further referring to the above-described stimulable phosphor sheet that carries a thin film of the alkali metal halide based stimulable phosphor, in consideration of various factors such as the diameter and growth of columnar crystals, an embossed pattern comprising a large number of projections is preferably formed on the specified surface of the substrate sheet S, with the maximum diameter, height and spacing being all adjusted to lie between 0.2 μm and 40 μm, preferably between 0.5 μm and 10 μm. As a result, phosphor crystals that have grown in a generally vertical direction are aligned very closely without leaving any significant gaps in the phosphor layer to produce a high-quality phosphor sheet capable of sharp image reproduction.

In the apparatus 10, the film depositing section 16 is provided downstream of the transfer section 14 in the pathway of the transport of the sheet S by the transport unit 12.

The film depositing section 16 consists of two vacuum retaining means 30 and 32, as well as a film deposition chamber 34. It is in this section that the sheet S having an embossed pattern formed on the specified surface in the transfer section 14 is provided with a phosphor layer deposited from CsBr:Eu.

The vacuum retaining means 30 and 32 maintain a vacuum in the interior of the film deposition chamber 34 (i.e., a vacuum chamber 40 to be described later) as the sheet S is brought into the film deposition chamber 34 or as it emerges therefrom.

The vacuum retaining means 30 and 32 are known vacuum sealers for use in continuous film deposition that comprise a casing to which evacuating means such as a vacuum pump is connected and which contains seal rolls, seal bars, seal blocks, etc. in its interior. Exemplary vacuum sealers that may be employed are disclosed in JP 6-88235 A and JP 9-143728 A.

The film deposition chamber 34 is for depositing CsBr:Eu to form a phosphor layer by binary vacuum evaporation. In the illustrated case, it is vacuum evaporation equipment comprising a vacuum chamber 40 and a thermal evaporating section 42 provided in the vacuum chamber 40.

A vacuum pump (evacuating means) not shown is connected to the vacuum chamber 12 in order to evacuate the interior of the system to a specified degree of vacuum. If desired, heating means may be provided within the vacuum chamber 40 and upstream of the film depositing section 16 in order to heat the sheet S in preparation for and during the deposition of a phosphor layer.

In the illustrated case, the film deposition chamber 34 may perform binary vacuum evaporation from cesium bromide (CsBr) and europium bromide (EuBrₓ, with x being typically from 2 to 3) so that a phosphor layer using CsBr:Eu as a stimulable phosphor is deposited on the substrate to produce a phosphor sheet.

In this process of depositing the phosphor layer, europium serves as an activator.

When the apparatus 10 of the invention is to be employed to produce stimulable phosphor sheets, the phosphor is by no means limited to CsBr:Eu and various other stimulable phosphors may be employed. Preferred stimulable phosphors are those which produce luminescence in the wavelength range of 300 nm-500 nm upon stimulation with exciting light at wavelengths in the range of 400 nm-900 nm. Details of such stimulable phosphors are given in JP 7-84588 B, JP 2-193100 A and JP 4-310906 A.

Particularly preferred stimulable phosphors are those which are based on alkali metal halides and represented by the following basic formula:

M^{I}X·aM^{II}X′₂·bM^{III}X″₃: zA

Where M^{I} is at least one alkali metal selected from the group consisting of Li, Na, K, Rb and Cs; M^{II} is at least one alkaline earth metal or divalent metal selected from the group consisting of Be, Mg, Ca, Sr, Ba, Ni, Cu, Zn and Cd; M^{III} is at least one rare earth element or trivalent metal selected from the group consisting of Sc, Y, La, Ce, Pr, Nd, Pm, Sm, Eu, Cd, Tb, Dy, Ho, Er, Tm, Yb, Lu, Al, Ga and In; A is at least one rare earth element or metal selected from the group consisting of Y, Ce, Pr, Nd, Sm, Eu, Gd, Tb, Dy, Ho, Er, Tm, Yb, Lu, Na, Mg, Cu, Ag, Tl and Bi; X, X′ and X″ are each at least one halogen selected from the group consisting of F, Cl, Br and I; a is a number within the range of 0≦a<0.5, b is a number within the range of 0≦b<0.5, and z is a number within the range of 0≦z<1.0.

In the basic formula set forth above, M^{I} preferably contains at least Cs, X preferably contains at least Br, and A is preferably Eu or Bi.

The materials from which the phosphor layer is deposited are not limited in any particular way and a material containing phosphors and a material containing an activator may be chosen as appropriate depending upon the stimulable phosphor to be prepared.

The vacuum chamber 40 is a known vacuum chamber (bell jar or vacuum vessel) that is commonly employed in vacuum evaporation equipment and which is typically made of iron, stainless steel or aluminum.

As already mentioned, a vacuum pump (not shown) is connected to the vacuum chamber 40. Again, the vacuum pump is not limited in any particular way and various types used in vacuum evaporation equipment may be employed if they can produce the required ultimate pressure. To mention a few, an oil diffusion pump, a cryogenic pump and a turbo molecular pump may be employed. If necessary, a cryogenic coil may be used as an auxiliary device. In the apparatus 10 designed for depositing the above-described phosphor layer, the ultimate pressure to be produced within the vacuum chamber 40 is preferably 6.7×10⁻³ Pa or less, more preferably 4.0×10⁻⁴ or less.

The thermal evaporating section 42 is provided within the film deposition chamber 34 (particularly in the vacuum chamber 40).

In the illustrated case, cesium bromide and europium bromide are used as starting materials in the film deposition chamber 34 and are individually heated to evaporate so that binary vacuum evaporation is performed. The thermal evaporating section 42 consists of two sub-sections, one for evaporating europium (and hereunder designated Eu evaporating sub-section 44) and the other for evaporating cesium (and hereunder designated Cs evaporating sub-section 46).

The Eu evaporating sub-section 44 is a site where europium bromide placed in an evaporating position (in a crucible) is evaporated by heating with a resistance heater 48.

The resistance heater 48 is not limited in any particular way and a variety of types commonly used in vacuum evaporation equipment may be employed. Hence, the heating element (source for evaporation) may be of any types commonly employed in resistance heaters, such as the boat type, filament type, crucible type, chimney type and K (Knudsen) cell. The power source (heating control means) may also be of any types commonly employed in resistance heaters, such as thyristor type, direct-current type and thermocouple feedback type.

An output of resistance heating is not limited to any particular value and may be set as appropriate in accordance with the activator material and the like. In the illustrated case, the output may be set between about 50 A and 1,000 A depending upon the resistance of the heater.

The Cs evaporating sub-section 46 is an electron beam epitaxy apparatus in which electron beams (EBs) emitted from an electron gun 55 are applied to an evaporation position (hearth) so that cesium bromide is thermally evaporated.

The electron gun 55 is not limited to any particular types and a variety of electron guns commonly used in vacuum evaporation may be employed, as exemplified by a 180° off-axis gun that deflects electron beams through 180° before they are incident at the evaporation position, also a 270° off-axis gun, and a 90° off-axis and straight advancing gun. In the illustrated case, the electron gun 55 is an example of the 270° off-axis gun.

The emission current and the EB accelerating voltage of the electron gun 55 are not limited to any particular values and they should be reasonably sufficient to fit the starting materials from which the phosphor layer is to be deposited and its thickness. In the illustrated case, as an example, the EB accelerating voltage is preferably between −1 kV and −30 kV whereas the emission current is set preferably between 50 mA and 2 A in the Cs evaporating sub-section 46.

The phosphor layer to be deposited to produce the phosphor sheet is very thick compared to conventional vacuum evaporated films and no thinner than about 200 μm; it is usually as thick as about 500 μm and may sometimes be thicker than 1,000 μm. The activator and the phosphor may be used at ratios between about 0.0005:1 and 0.01:1 in terms of molar concentration, so that the greater part of the phosphor layer is occupied by the phosphor.

To meet these requirements, in a preferred embodiment of the film deposition chamber 34, the Cs evaporating sub-section 46 has means 52 for supplying cesium bromide.

In the illustrated case, the basic components of the supply means 52 are a cylinder 54, a piston 56, a casing 58 and an ascending/descending means (motor) 60.

The cylinder 54 penetrates the bottom of the vacuum chamber 12 to protrude partially to the outside and is fixed to the outer wall surface of the vacuum chamber 12 such that its upper end coincides with the position of exposure to electron beams. In the illustrated case, the cylinder 54 serves as a hearth and its upper end is the position where cesium bromide is evaporated.

The piston 56 comprises a cylindrical piston head 56a which is loosely fitted into the cylinder 54 and a piston pin 56b whose top end is fixed to the piston head 56a. The piston pin 56b engages the ascending/descending means 60 which causes the piston 56 to either ascend or descend (in the direction of arrow a).

The open end of the cylinder 54 is enclosed with the casing 58 so that the interior of the vacuum chamber 40 is kept airtight. By means of a bearing (not shown), the piston pin 56b is axially supported and kept airtight in the casing 58 so that it can make reciprocating movement in the direction of arrow a.

Cesium bromide shaped into a cylindrical form smaller than inside diameter of the cylinder 54 is placed within the cylinder 54 such that it rests on the piston head 56a.

As the cesium bromide in the evaporation position is consumed to have a film deposited on the substrate, the ascending/descending means 60 drives the piston 56 to get the cylindrical cesium bromide upward. This always allows cesium bromide to be supplied to the top of the cylinder 54, or the evaporation position, assuring effective deposition of a thick film in excess of 200 μm.

The material supply means is not limited to the illustrated embodiment and a variety of material supply means commonly used in the vacuum evaporation equipment may be employed. To give a few examples, the variety of material supply means described in Japanese Patent Application No. 2001-296364 may be used with advantage.

In the invention, the film deposition chamber 34 (in the film depositing section 16) is not limited to a type having only one unit of the binary thermal evaporating section 42 and various other designs are possible. For example, two or more combinations of evaporating means by EB and resistance heating may be employed to provide a complex system of vacuum evaporation. Alternatively, a single means of evaporating a film depositing material containing an activator may be combined with two or more means of evaporating a film depositing material containing a phosphor to provide a complex system of vacuum evaporation. Yet another candidate is a unitary evaporation system which performs vacuum evaporation using a single film depositing material.

If desired, the evaporating means by EB and resistance heating may be combined with an evaporating means that adopts yet another heating method.

In the apparatus 10 of the invention, the vacuum film depositing means is not limited to the illustrated case of vacuum evaporation and all kinds of vacuum film depositing means including sputtering and CVD can be adopted. An optimum method of vacuum film deposition may be chosen as appropriate in accordance with various factors including the material from which a film is to be deposited, the desired rate of deposition and the film thickness.

As an example, in the illustrated case of producing a phosphor sheet, there is a need to deposit a very thick (≧200 μm) film as mentioned above, so vacuum evaporation is preferably employed from a productivity viewpoint.

From the viewpoints of the composition and characteristics of the phosphor layer as exemplified by the precision in the addition of an activator in a very small amount and the state of its dispersion, the illustrated case of binary evaporation is preferably performed by thermally evaporating the activator and the phosphor separately. A particularly preferred case of binary vacuum evaporation is by evaporating the activator-containing material and the phosphor-containing material by resistance heating and EB, respectively, because the two starting materials can be placed in evaporation positions that are sufficiently close to each other so that not only it is possible to deposit at all times a phosphor layer having good characteristics such as the ability to reproduce sharp image but also it is possible to ensure satisfactory rate of film deposition.

The sheet S provided with an embossed pattern on the specified surface as it is transported through the transfer section 14 is forwarded into the film deposition chamber 34 via the vacuum retaining means 30 and as it is transported through the chamber 34, the patterned surface of the sheet S (which is its lower side in FIG. 1) is provided with a phosphor layer (CsBr:Eu) that is deposited from the europium bromide evaporated by resistance heating and from the cesium bromide evaporated by EB and which is patterned in accordance with the previously formed pattern. In the illustrated case, as already mentioned, the pattern formed on a surface of the sheet S consists of a large number of projections P and they serve as bases on which columnar crystals grow to form a phosphor layer having a pattern which, as shown conceptually in FIG. 2B, is an array of separate independent columnar crystals.

The sheet S now carrying the phosphor layer is forwarded into the vacuum retaining means 32, passes through it, emerges from the film deposition chamber 34, and advances to the take-up section 24.

Thus, by means of the apparatus 10, the formation of an embossed pattern and the formation of a patterned functional thin film by vacuum film deposition techniques can be performed continuously on a surface of a web of sheet S (substrate) and a sheeting having a patterned functional thin film such as a phosphor layer comprising an array of columnar crystals as described above can be manufactured continuously with high productivity and efficiency.

The take-up section 24 is a known sheeting take-up means that rotates the take-up roller 22 in accordance with the transporting speed of the sheet S by the transport unit 12 so that the sheet S carrying the phosphor layer is rewound onto the take-up roller 22 into roll form.

While the apparatus of the invention for producing the sheeting has been described above in detail, the invention is by no means limited to the foregoing example and various modifications and improvements can of course be made without departing from the scope and spirit of the invention.

For example, in the illustrated case, pattern formation and vacuum film deposition are performed as the sheet S is transported continuously. Although this is an embodiment for achieving high productivity, it is by no means the sole case of the invention.

In one alternative, pattern formation and vacuum film deposition are performed on the sheeting as it is transported intermittently (i.e., a length of sheeting is transported, stopped, film deposition is performed, and a length of sheeting is transported again). In this intermittent transport of the sheeting, the pattern transfer means may be other than the transfer roller 26 shown in FIG. 1, as exemplified by a stamper, or a plate having an embossed pattern, that is pressed against the stationary sheeting in order to transfer the pattern.

In yet another modification, the sheet S having the phosphor layer deposited is not taken up in roll form but may instead be cut to a specified length in a location downstream of the film depositing section 16.

As already noted, the apparatus of the invention for producing the sheeting is in no way limited to the apparatus for producing phosphor sheets and it can advantageously be employed to produce a variety of sheetings that comprise a substrate having a patterned functional thin film by vacuum film deposition techniques.

For example, it may be employed to produce microlens arrays and other optical components by depositing patterned optical films or, alternatively, magnetic recording media such as those for use on super-high density FDs may be produced by depositing patterned magnetic films. In addition, the apparatus may be employed to produce the phosphor layer, so-called scintillator, disclosed in JP 2001-283731 A, supra.

In whichever case, the pattern of the functional thin film (the embossed pattern to formed on the sheet in accordance with said pattern, namely, the embossed pattern of the pattern transfer means) may be chosen as appropriate in accordance with a specific use of the sheeting with a thin film.

As described in detail on the foregoing pages, by means of the apparatus of the invention for producing the sheeting, the formation of an embossed pattern and the formation of a patterned functional thin film by vacuum film deposition techniques can be performed continuously on a surface of a web of sheet or sheeting having a patterned functional thin film such as a stimulable phosphor sheet having a stimulable phosphor layer comprising an array of columnar crystals can be manufactured with high productivity and efficiency.

What is claimed is:

1. An apparatus for producing sheetings, comprising:
transport means for transporting a web of sheeting along its length direction;
pattern transfer means for forming a pattern on a surface of said sheeting by transfer, said pattern transfer means being provided in a pathway where said web of sheeting is transported by said transport means;
film depositing means for performing vacuum film deposition on the patterned surface of said web of sheeting, said film depositing means being provided downstream of said pattern transfer means in said pathway; and
pressure retaining means for retaining pressure within said film depositing means, said pressure retaining means being provided in a region of said film depositing means into which said web of sheeting is transported and in a region of said film depositing means from which said web of sheeting emerges.

2. The apparatus according to claim 1, wherein said transport means has delivery sub-means for delivering said web of sheeting from a roll of sheeting and take-up sub-means for taking up said web of sheeting on the surface of which the vacuum film deposition is performed.

3. The apparatus according to claim 1, wherein said pattern transfer means comprises a transfer roller having up and down areas on its cylindrical surface that correspond to the pattern to be transferred and a nip roller that cooperates with said transfer roller to hold said web of sheeting between the transfer and the nip rollers.
